(19) United States
(12) Patent Application Publication
(10) Pub. No.: US 2024/0396291 A1
(43) Pub. Date: Nov. 28, 2024

(54) LIGHT SOURCE MODULE AND LIGHT OUTPUT METHOD

(71) Applicant: NEC Corporation, Tokyo (JP)

(72) Inventors: Taro KANEKO, Tokyo (JP); Isao TOMITA, Tokyo (JP)

(73) Assignee: NEC Corporation, Tokyo (JP)

(21) Appl. No.: 18/658,031

(22) Filed: May 8, 2024

(30) Foreign Application Priority Data
May 26, 2023 (JP) 2023-087315

(51) Int. Cl. H01S 5/02253; H01S 5/00; H01S 5/0239; H01S 5/024

(52) U.S. Cl. CPC H01S 5/02253; H01S 5/0064; H01S 5/0239; H01S 5/02415; H01S 5/02438

(57) ABSTRACT

An object is to realize miniaturization of a light source module with a simple configuration. A cooling unit is provided to the housing to be contained in the housing. A light source is provided to the cooling unit and outputs light. A lens is provided to the cooling unit. The light output from the light source is incident on the lens. The lens deflects a travelling direction of the incident light toward the cooling unit and outputs the deflected light. An optical output unit is provided to the housing and outputs the light output from the lens to the outside of the housing.

### INCORPORATION BY REFERENCE

This application is based upon and claims the benefit of priority from Japanese patent application No. 2023-87315, filed on May 26, 2023, the disclosure of which is incorporated herein in its entirety by reference.

### TECHNICAL FIELD

The present disclosure relates to a light source module and a light output method.

### BACKGROUND ART

In an optical communication technology field, for example, an optical transceiver provided with a transmitter and a receiver for transmitting and receiving optical signals is widely used. In an optical transceiver, a light source module that outputs light of a predetermined wavelength is provided to transmit an optical signal by modulating light of a wavelength for transmission and to cause an optical signal to interfere with light of a wavelength for reception to receive the optical signal.

In the light source module, laser light output from a light source is converged by a lens and then output to other optical components via a connector or the like (Japanese Unexamined Patent Application Publication Nos. 2017-005122 and 2002-252420, and International Patent Publication 2020/166502). A light source module that is provided with an isolator to prevent reflected light from returning to a light source (International Patent Publication No. WO 2020/166502).

### SUMMARY

Meanwhile, optical transceivers need to be provided with various components such as transmitters, receivers, optical receptacles, and various connectors, as well as light source modules. However, since the space in a housing of the optical transceiver have limited, a plurality of components need to be efficiently contained in the housing. Therefore, further miniaturization of the light source module is required.

The present disclosure has been made in view of the above circumstances, and aims to realize miniaturization of a light source module with a simple configuration.

An aspect of the present disclosure is a light source module including: a housing; a cooling unit provided to the housing to be contained in the housing; a light source provided to the cooling unit and configured to output light; a lens provided to the cooling unit, on which the light output from the light source is incident, and configured to deflect a travelling direction of the incident light toward the cooling unit and output the deflected light; and an optical output unit provided to the housing and configured to output the light output from the lens to the outside of the housing.

An aspect of the present disclosure is a method of outputting light including: outputting light from a light source provided to a cooling unit that is provided to a housing to be contained in the housing; by a lens provided to the cooling unit, deflecting a travelling direction of the light output from the from the light source and incident on the lens toward the cooling unit and outputting the deflected light; and by an optical output unit provided to the housing, outputting the light output from the lens to the outside of the housing.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 schematically shows a configuration of a light source module according to a first example embodiment;

FIG. 2 shows the configuration of the light source module according to the first example embodiment in more detail;

FIG. 3 schematically shows a configuration of a general light source module;

FIG. 4 schematically shows a configuration of a light source module according to a second example embodiment; and

FIG. 5 schematically shows a configuration of a light source module according to a third example embodiment.

### EXAMPLE EMBODIMENT

Hereinafter, example embodiments of the present disclosure will be described with reference to the drawings. In the drawings, the same element is denoted by the same reference numeral, and redundant description is omitted as necessary.

### First Example Embodiment

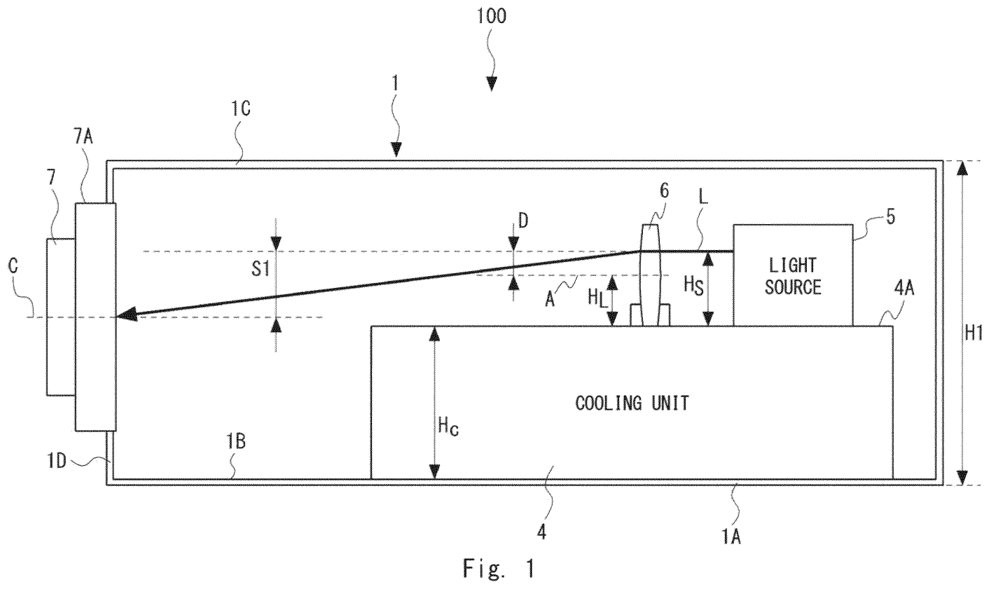

A light source module according to a first example embodiment will be described below. FIG. 1 schematically shows a configuration of a light source module 100 according to the first example embodiment. The light source module 100 includes a housing 1, a cooling unit 4, a light source 5, a lens 6, and an optical connector 7.

The housing 1 is a box-shaped member in which a cavity is formed. The longitudinal direction of the housing 1 is the horizontal direction of the plane of FIG. 1. The housing 1 includes a bottom plate 1A and a top plate 1C that are rectangular plate-like members arranged to face each other in parallel. The normal direction of the rectangle of the bottom plate 1A and the top plate 1C is the vertical direction of the plane of FIG. 1. Sides of the bottom plate 1A and sides of the top plate 1C are connected by side plates perpendicular to the bottom plate 1A and the top plate 1C. In FIG. 1, reference numeral 1D denotes a side plate connecting the left end of the bottom plate 1A and the left end of the top plate 1C. Various components constituting the light source module 100 are mounted on a bottom surface 1B that is an inner surface of the bottom plate 1A of the housing 1.

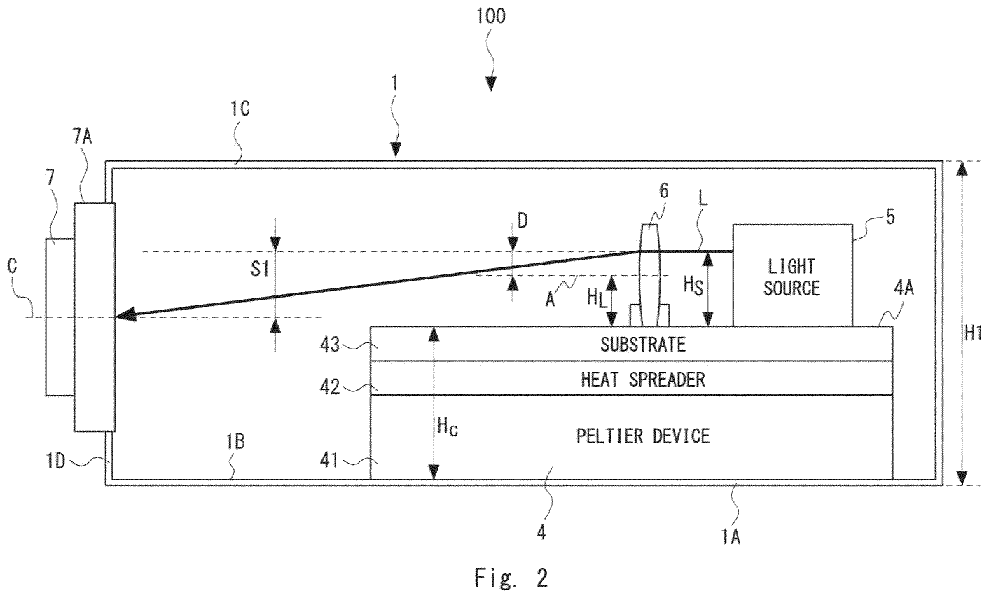

The cooling unit 4 is a member for cooling the light source 5 that is a heating body. The cooling unit 4 is mounted on the bottom surface 1B of the housing 1. Therefore, a bottom surface of the cooling unit 4 is in contact with the bottom surface 1B. Here, a dimension of the cooling unit 4 in a height direction is H_{C}. A configuration of the cooling unit 4 will be described below. FIG. 2 shows the configuration of the light source module 100 according to the first example embodiment in more detail. The cooling unit 4 includes a Peltier device 41 provided on the bottom surface 1B, a heat spreader 42 provided on the Peltier device 41, and a substrate 43 mounted on the heat spreader 42.

The light source 5 is provided on the substrate 43 and outputs laser light L of a predetermined wavelength to the lens 6. In the present example, an emission direction of the laser light L is in the horizontal direction of the plane of FIG. 2, that is, a direction parallel to an upper surface 4A of the cooling unit 4. A distance between the optical axis of the laser light L output from the light source 5 and the upper surface 4A of the cooling unit 4 is H_{S}. The light source 5 may be configured as various light sources such as a DFB (Distributed FeedBack) laser element or a laser module composed of a laser element and an external resonator.

The heat generated when the light source 5 outputs the laser light L is conducted through the substrate 43 to the heat spreader 42 that is provided to equalize heat density in the cooling unit 4. Thus, the heat conducted from the substrate 43 is diffused by the heat spreader 42 and thereby equalized. Then, the Peltier device 41 cools the heat spreader 42 and the heat is removed. As a result, the light source 5 can be kept at a predetermined temperature.

The lens 6 is a lens that converges incident light like a convex lens. The lens 6 is arranged in such a manner that an axis A thereof is parallel to the optical axis of the laser light L output from the light source 5. A distance between the axis A and the upper surface 4A of the cooling unit 4 is H_{L}. Further, the lens 6 is arranged in such a manner that the laser light L from the light source 5 is incident on a position upper than the axis A, i.e., a position offset by a distance D in a direction away from the cooling unit 4. Therefore, H_{S}=H_{L}+D. As a result, the laser light L is deflected downward by the lens 6, i.e., in a direction approaching the cooling unit 4, and is output toward the optical connector 7.

The optical connector 7 is provided on the side plate 1D on an emission side of the housing 1. The laser light L is output to the outside of the light source module 100 through a waveguide structure provided at the center C of the optical connector 7. Although not shown, the optical connector 7 is connected to an external optical component of the light source module 100 by an optical fiber, for example, and the laser light L is guided to the external optical component through the optical fiber. The optical connector 7 is simply referred to as an optical output unit.

In the present configuration, a height dimension of the housing 1 including the cooling unit 4, the light source 5 and the lens 6, that is, a height dimension of the side plate 1D, is H1. The optical connector 7 is attached to the side plate 1D having the height H1 not to interfere with the bottom plate 1A and the top plate 1C.

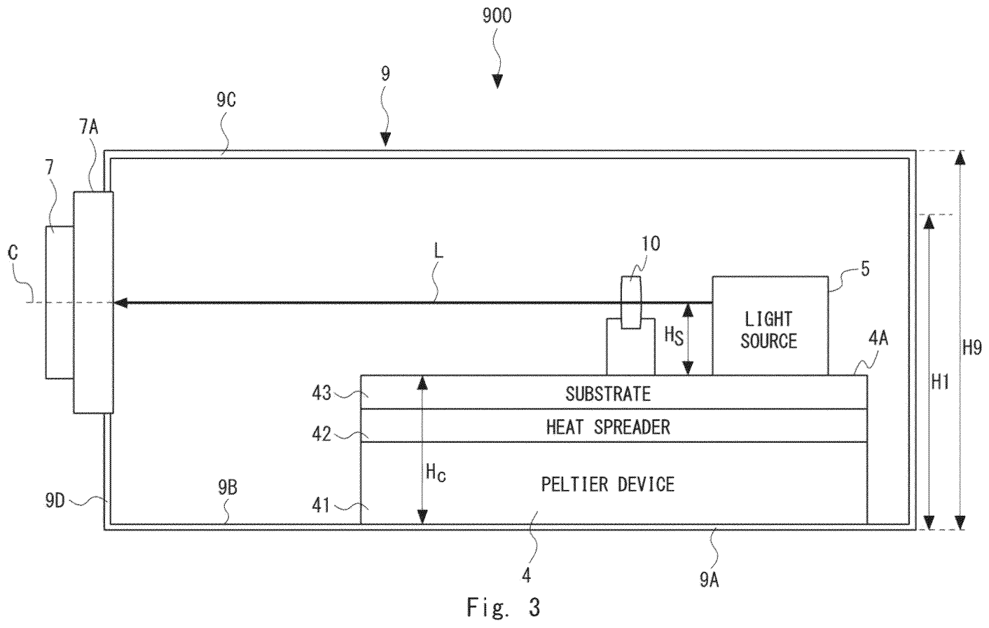

Next, the effect of the deflection of the laser light L in the present configuration will be described. First, as a comparative example, dimensions of a general light source module in which laser light is not deflected will be discussed. FIG. 3 schematically shows a configuration of a general light source module 900. The general light source module 900 has a configuration in which the housing 1 and the lens 6 of the light source module 100 are replaced with a housing 9 and a lens 10. A bottom plate 9A, a bottom surface 9B, a top plate 9C, and a side plate 9D of the housing 9 correspond to the bottom plate 1A, the bottom surface 1B, the top plate 1C, and the side plate 1D of the housing 1, respectively, and their details will be omitted.

The lens 10 is a lens that converges incident light like the lens 6. The lens 10 is arranged in such a manner that an axis thereof coincides with the optical axis of the laser light L output from the light source 5. As a result, the laser light L is converged by the lens 10 and then travels straight toward the center C of the optical connector 7. In this case, the position of the center C of the optical connector 7 is the position of the optical axis of the laser light L. Therefore, a distance between the center C of the optical connector 7 and the bottom surface 9B is H_{C}+H_{S}.

In the light source module 900, the cooling unit 4 is also provided to efficiently cool the mounted light source 5. However, as described above, since the cooling unit 4 includes a plurality of members stacked in the height direction, it is difficult to reduce the dimension H_{C} in the height direction.

Therefore, in the light source module 900, the optical axis of the laser light L is relatively high above the bottom surface 9B by H_{C}+H_{S}, and the center C of the optical connector 7 for outputting the laser light L to the outside is also located at a position biased above the housing 9. Accordingly, an upper end 7A of the optical connector 7 projects upward from an upper end of the lens 10 and an upper end of the light source 5. In FIG. 3, the upper end of the lens 10 is higher than the upper end of the light source 5, and the upper end 7A of the optical connector 7 projects upward from the upper end of the lens 10.

As a result, regardless of the positions of the upper ends of the lens 10 and the light source 5, a height dimension H9 of the housing 9 needs to be increased to enable the optical connector 7 to be attached to the side plate 9D.

For example, in the general light source module 900, the height of the optical connector 7, i.e., H_{C}+H_{S} that is the distance between the center C of the optical connector 7 and the bottom surface 9B, is 2.4 mm, and the height dimension H9 of the housing 9 in this case is 4.0 mm.

In contrast, in the light source module 100 according to the present example embodiment, the position of the center C of the optical connector 7 where the laser light L enters is shifted downward by deflecting the laser light L downward by the lens 6. As shown in FIGS. 1 and 2, the position of the center C of the optical connector 7 is shifted downward by S1 with respect to the optical axis of the laser light L output from the light source 5. As a result, a distance between the bottom surface 1B and the center C of the optical connector 7 is H_{C}+H_{S}−S1.

Therefore, the light source module 100 can shorten the distance between the bottom surface 1B and the center C of the optical connector 7 by S1 compared with that of the general light source module 900. Accordingly, the position of the upper end 7A of the optical connector 7 is shifted downward by S1, and protrusion of the upper end 7A of the optical connector 7 with respect to the lens 10 and the light source 5 can be prevented or an amount of the protrusion can be reduced. As a result, the height dimension H1 of the housing 1 can be reduced compared with the height dimension H9 of the housing 9.

For example, if the amount of shift caused by the laser light being deflected in the present configuration is 0.5 mm, the height between the bottom surface 1B and the center C of the optical connector 7 is 1.9 mm by being shifted downward by 0.5 mm compared with the general light source module 900. At this time, the dimension H1 in the height direction of the housing 1 can be shortened to 3.5 mm.

According to the present configuration, the position of the optical connector can be offset downward by deflecting the optical axis of the laser light L downward. Thus, the dimension of the light source module in the height direction can be reduced by a simple configuration without additional components, and the light source module can be miniaturized.

### Second Example Embodiment

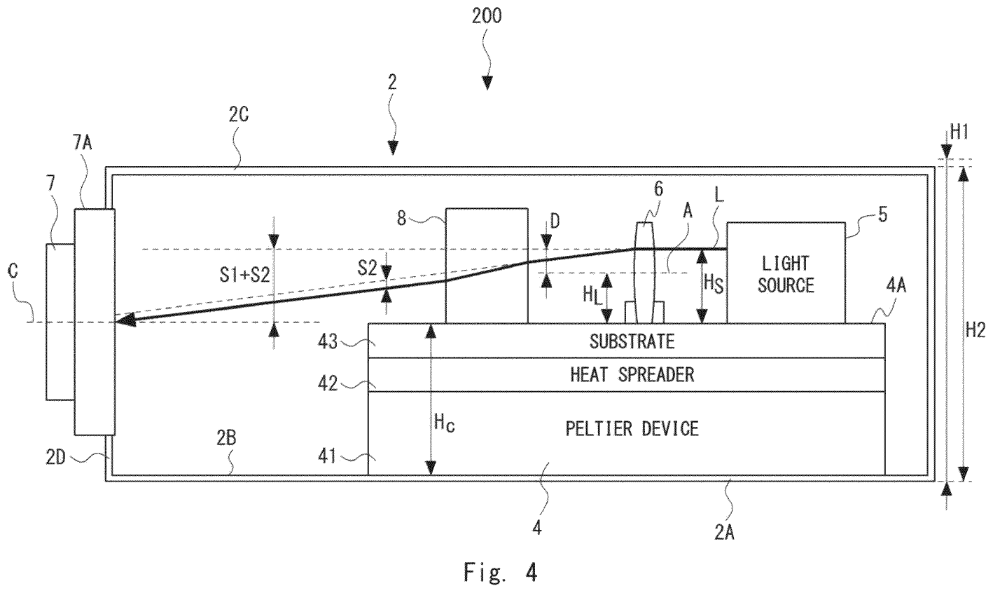

A light source module according to a second example embodiment will be described below. FIG. 4 schematically shows a configuration of a light source module 200 according to the second example embodiment. Compared with the light source module 100 according to the first example embodiment, the light source module 200 has a configuration in which the housing 1 is replaced with the housing 2 and an isolator 8 is further provided. A bottom plate 2A, a bottom surface 2B, a top plate 2C, and a side plate 2D of the housing 2 correspond to the bottom plate 1A, the bottom surface 1B, the top plate 1C, and the side plate 1D of the housing 1, respectively, and their details will be omitted.

The isolator 8 is provided on the substrate 43 of the cooling unit 4 at a position where the laser light L deflected by the lens 6 enters. This prevents the laser light L from returning to the lens 6 and the light source 5.

The laser light L deflected by the lens 6 enters an incident surface 8A of the isolator 8 perpendicular to the optical axis of the laser light L output from the light source 5 at a predetermined incident angle. Since a refractive index of the medium of the isolator 8 is higher than that of the surrounding atmosphere in which the laser light propagates, the laser light L is refracted downward at the incident surface 8A. The laser light L refracted downward at the incident surface 8A propagates through the medium of the isolator 8 and reaches an emission surface 8B parallel to the incident surface 8A. After being refracted upward at the emission surface 8B, the laser light L is output toward the center of the optical connector 7 at the same emission angle as the incident angle when it enters the incident surface 8A.

As a result, the laser light L output from the emission surface 8B is shifted downward due to refraction by S2 with respect to the laser light L entering the incident surface 8A. As a result, the position of the center C of the optical connector 7 that the laser light L output from the emission surface 8B reaches can be further shifted downward by S2 compared with the case of the light source module 100.

Therefore, protrusion of the upper end 7A of the optical connector 7 with respect to the lens 6 and the light source 5 can be more easily prevented, or the amount of protrusion can be more easily reduced. As a result, according to the present configuration, a height dimension H2 of the housing 2 can be reduced compared with the height dimension H1 of the housing 1. Therefore, the dimension in the height direction of the light source module can be further reduced to realize further miniaturization of the light source module.

### Third Example Embodiment

In the light source module 200 according to the second example embodiment, when the position of an upper end of the isolator 8 is higher than the positions of the upper ends of the lens 6 and the light source 5, the height dimension of the housing 2 is constrained by the upper end of the isolator 8. Thus, it is desirable to be able to miniaturize the isolator 8. However, it may be assumed that the miniaturization of the isolator 8 is limited and it is thereby difficult to miniaturize the isolator 8. Therefore, in the present example embodiment, a light source module that avoids interference between the isolator and the housing by changing an arrangement of an isolator will be described.

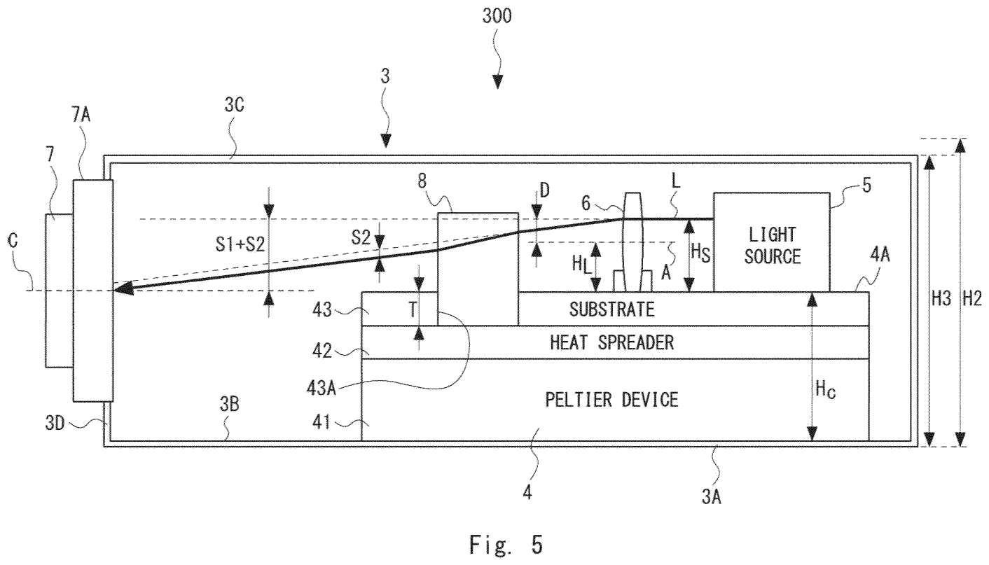

FIG. 5 schematically shows a configuration of a light source module 300 according to a third example embodiment. Compared with the light source module 200 according to the second example embodiment, the light source module 300 has a configuration in which the housing 2 is replaced with a housing 3. A bottom plate 3A, a bottom surface 3B, a top plate 3C, and a side plate 3D of the housing 3 correspond to the bottom plate 2A, the bottom surface 2B, the top plate 2C, and the side plate 2D of the housing 2, respectively, and their details will be omitted.

The isolator 8 is provided on the heat spreader 42 by being inserted through a through hole 43A penetrating the substrate 43. Therefore, in the light source module 300, an installation position of the isolator 8 is moved downward by a thickness T of the substrate 43 compared with the light source module 200 according to the second example embodiment.

Thus, even if the height dimension of the isolator 8 is higher than the height dimensions of the lens 6 and the light source 5, the isolator 8 can be prevented from protruding upward from the lens 6 and the light source 5, or the amount of protrusion can be reduced.

As a result, according to the present configuration, a height dimension H3 of the housing 3 can be reduced compared with the height dimension H2 of the housing 2. As a result, the height dimension of the light source module can be further reduced to realize further miniaturization of the light source module.

### Other Example Embodiments

It should be noted that the present invention is not limited to the above example embodiments and can be suitably modified to the extent that it does not deviate from the purpose. For example, in the above example embodiments, the position and direction have been explained in terms of vertical relation for the sake of simplicity of explanation, but this is only an example. Depending on the posture in which the light source module is mounted in another device, the vertical relation may be changed appropriately, such as by reversing.

In the above-described example embodiment, for the sake of simplicity, the inside of the housing is provided with the cooling unit, the light source, the lens, and the isolator, but the inside of the housing may be provided with other components as appropriate. The housing is also provided with an optical connector, but the housing may be provided with other components as appropriate.

The shapes, arrangement positions, and arrangement postures of the lenses and isolators described in the above-described example embodiments are merely examples. Other shapes, arrangement positions, and arrangement postures may be provided as appropriate as long as the laser light can be similarly guided.

In the third example embodiment, the isolator 8 has been described as being inserted into the through hole 43A penetrating the substrate 43, but this is only an example. For example, the isolator 8 may be inserted into a hole formed on the substrate 43 that does not penetrate the substrate 43, a hole that penetrates the substrate 43 and then reaches the heat spreader 42, or a hole that penetrates the substrate 43 and the heat spreader 42, and then reaches the Peltier device 41.

The first to third example embodiments can be combined as desirable by one of ordinary skill in the art.

While the disclosure has been particularly shown and described with reference to example embodiments thereof, the disclosure is not limited to these example embodiments.

It will be understood by those of ordinary skill in the art that various changes in form and details may be made therein without departing from the spirit and scope of the present disclosure as defined by the claims.

What is claimed is:

1. A light source module comprising:
a housing;
a cooling unit provided to the housing to be contained in the housing;
a light source provided to the cooling unit and configured to output light;
a lens provided to the cooling unit, on which the light output from the light source is incident, and configured to deflect a travelling direction of the incident light toward the cooling unit and output the deflected light; and
an optical output unit provided to the housing and configured to output the light output from the lens to the outside of the housing.

2. The light source module according to claim 1, wherein
an optical axis of the light output from the light source is parallel to an axis of the lens, and
the light output from the light source enters the lens at a position apart from the axis of the lens by a predetermined distance.

3. The light source module according to claim 1, wherein
the cooling portion is provided on an inner surface of the housing,
the light source and the lens are provided on an opposite surface of the cooling unit opposite to a surface attached to the housing, and
the light output from the light source is output in a direction parallel to the opposite surface of the cooling unit.

4. The light source module according to claim 1, wherein
the housing includes a bottom plate on which the cooling unit is provided, a top plate that faces the bottom plate and is parallel to the bottom plate, and a side plate that is perpendicular to the bottom plate and the top plate, and connects the bottom plate and the top plate, and
the optical output unit is provided on the side plate not to interfere with the bottom plate and the top plate.

5. The light source module according to claim 1, further comprising an isolator provided on the cooling unit and on which the light output from the lens is incident, wherein
the light output from the lens is incident on an incident surface of the isolator at a predetermined incident angle,
the light incident on the incident surface is further deflected in a direction toward the cooling unit by refraction and propagates through the isolator, and
the light propagating through the isolator and reaching an emission surface of the isolator is deflected in a direction opposite to the cooling unit by refraction and output at an emission angle that is the same as the incident angle.

6. The light source module according to claim 5, wherein the isolator is provided to the cooling unit by being partially inserted through a hole provided in the cooling unit.

7. A method of outputting light comprising:
outputting light from a light source provided to a cooling unit that is provided to a housing to be contained in the housing;
by a lens provided to the cooling unit, deflecting a travelling direction of the light output from the from the light source and incident on the lens toward the cooling unit and outputting the deflected light; and
by an optical output unit provided to the housing, outputting the light output from the lens to the outside of the housing.
